(19) United States
(12) Patent Application Publication
(10) Pub. No.: US 2010/0283141 A1
(43) Pub. Date: Nov. 11, 2010

(54) SEMICONDUCTOR CHIP PACKAGE

(76) Inventors: Chun-Wei Chang, Taipei County (TW); Tung-Hsien Hsieh, Changhua County (TW); Chia-Hui Liu, Taichung County (TW)

Correspondence Address: NORTH AMERICA INTELLECTUAL PROPERTY CORPORATION, P.O. BOX 506, MERRIFIELD, VA, 22116, US

(21) Appl. No.: 12/463,431

(22) Filed: May 11, 2009

(51) Int. Cl. H01L 23/49

(52) U.S. Cl. 257/690; 257/E23.024

(57) ABSTRACT

A semiconductor chip package includes a chip; first and second connection pads arranged in a matrix and disposed about the chip, and the first and second connection pads have different bottom surface shapes when viewed from a bottom of the QFN package; bonding pads provided on an active surface of the chip and being electrically connected with corresponding said connection pads through bonding wires; and a package body encapsulating the chip, the bonding wires and an upper portion of each of the connection pads such that a lower portion of each of the connection pads extends outward from a bottom of the package body.

### BACKGROUND OF THE INVENTION

1. Field of the Invention

The present invention relates to semiconductor chip packages, and more particularly, to a chip package having oval projecting pads at the bottom of the chip package.

2. Description of the Prior Art

Low-pin-count chip packages are becoming popular as a low-cost solution and are thus widely used in this industry because the cost of the low-pin-count chip package is lower than that of the thin and fine pitch BGA (TFBGA).

With increased improvement in semiconductor technology, operating speed and design complexity thereof are continuously increased. To respond to the needs of improved semiconductor technology, efficient semiconductor packing technologies are desirable, such as high-density packaging. The quad flat non-lead (QFN) package is one popular of low-pin-count high-density package type. Since the QFN has relatively shorter signal traces and a faster speed for signal transmission, it has become the mainstream for the chip package with low pin count and is suitable for the high-frequency chip package.

FIG. 1 is a schematic, cross-sectional view of a QFN package 100 according to the prior art. FIG. 2 is a bottom view of the QFN package of FIG. 1. As shown in FIG. 1 and FIG. 2, a QFN package 100 includes a chip 110 attached to a die pad 150, a plurality of inner connection pads 160′ disposed about a periphery of the die pad 150 and a plurality of outer connection pads 160″ disposed about the inner connection pads 160′. A plurality of bonding pads 112 are provided on an active surface of the chip 110 and are electrically connected with the corresponding inner and outer connection pads 160′ and 160″ through gold wires 114.

A package body 120 encapsulates the chip 110, the gold wires 114, an upper portion of the die pad 150 and an upper portion 160a of each of the inner and outer connection pads 160′ and 160″ such that a lower portion 160b of each of the inner and outer connection pads 160′ and 160″ extends outward from the bottom of the package body 120. As best seen in FIG. 2, typically, the inner and outer connection pads 160′ and 160″ have a circular shape when viewed from the bottom of the chip package 100.

One drawback of the aforesaid QFN package 100 is that as the pitch of the inner and outer connection pads 160′ and 160″ becomes narrower, it is inevitable to use a printed circuit board (PCB) having a finer trace width. Hence, the cost is increased.

FIG. 3 demonstrates a partial trace layout of a PCB for the QFN package 100 of FIG. 1. For example, when a design rule including a pitch (P) of 0.5 mm and a circle pad diameter (C) of 0.27 mm is employed, it is required to use a PCB having a fine trace width (W) of 3 mil. Generally, the cost of the PCB with 3 mil trace width is about 5%-10% higher than that of a PCB having a trace width of 4 mil. It is desirable to use a PCB with a greater trace width in order reduce the cost.

### SUMMARY OF THE INVENTION

It is one object of the invention to provide an improved QFN package in order to overcome the shortcomings of the above-mentioned prior art.

To these ends, according to one aspect of the present invention, there is provided a quad flat non-lead (QFN) package including a chip; a plurality of first and second connection pads arranged in a matrix and disposed about the chip, wherein the first and second connection pads have different bottom surface shapes when viewed from a bottom of the QFN package; a plurality of bonding pads provided on an active surface of the chip and being electrically connected with corresponding said connection pads through bonding wires; and a package body encapsulating the chip, the bonding wires and an upper portion of each of the connection pads such that a lower portion of each of the connection pads extends outward from a bottom of the package body.

In one aspect, a semiconductor chip package includes a chip; a plurality of inner connection pads disposed about a periphery of the chip; a plurality of outer connection pads disposed between the plurality of inner connection pads and a periphery of the semiconductor chip package, wherein one of the outer connection pads has an oval shape when viewed from a bottom of the semiconductor chip package; a plurality of bonding pads provided on an active surface of the chip and being electrically connected with corresponding said inner and outer connection pads through bonding wires; and a package body encapsulating the chip, the bonding wires and an upper portion of each of the inner and outer connection pads such that a lower portion of each of the inner and outer connection pads extends outward from a bottom of the package body.

In another aspect, a semiconductor chip package includes a chip; a plurality of inner connection pads disposed about a periphery of the chip; a plurality of outer connection pads disposed between the plurality of inner connection pads and the periphery of the chip, wherein one of the outer connection pads has a rectangular shape with a long side and a short side when viewed from a bottom of the semiconductor chip package; a plurality of bonding pads provided on an active surface of the chip and being electrically connected with corresponding said inner and outer connection pads through bonding wires; and a package body encapsulating the chip, the bonding wires and an upper portion of each of the inner and outer connection pads such that a lower portion of each of the inner and outer connection pads extends outward from a bottom of the package body.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional view of a QFN package according to the prior art.

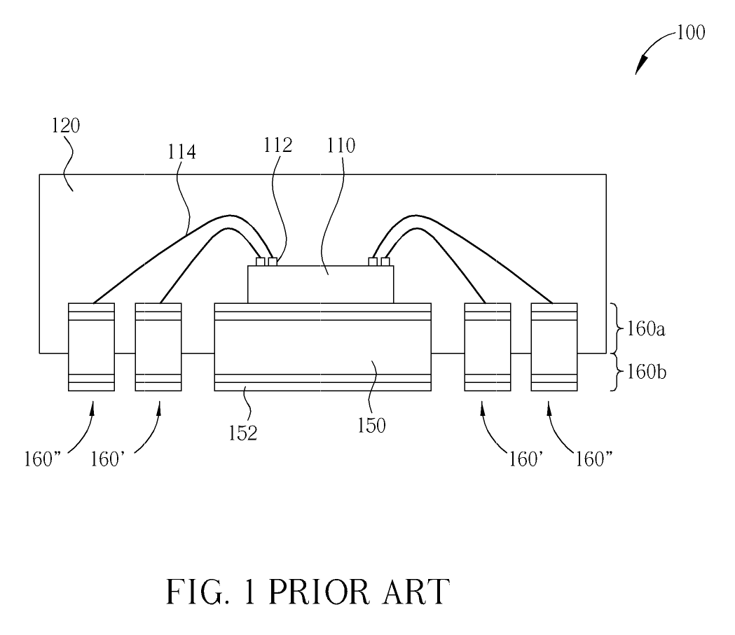

FIG. 2 is a bottom view of the QFN package of FIG. 1.

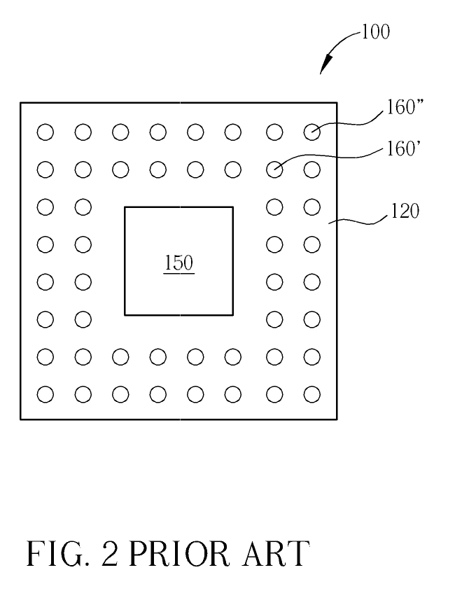

FIG. 3 demonstrates a partial trace layout of a PCB for the QFN package of FIG. 1.

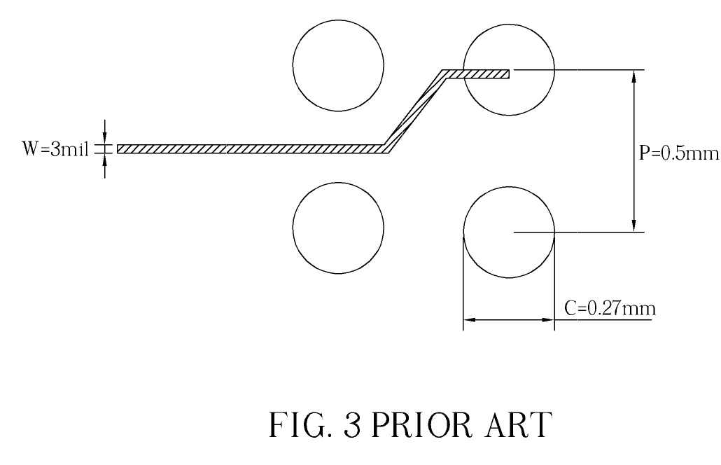

FIG. 4 is a schematic, cross-sectional view of a QFN package according to one embodiment of this invention.

FIG. 5 is a bottom view of the QFN package of FIG. 4.

FIG. 6 demonstrates a partial trace layout of a PCB for the QFN package of FIG. 4.

FIG. 7 is a schematic bottom view of a QFN package in accordance with another embodiment of this invention.

FIG. 8 is a schematic bottom view of a QFN package in accordance with yet another embodiment of this invention.

FIG. 9 demonstrates a partial trace layout of a PCB particularly for the QFN package of FIG. 8.

FIG. 10 is a schematic bottom view of a QFN package in accordance with yet another embodiment of this invention.

### DETAILED DESCRIPTION

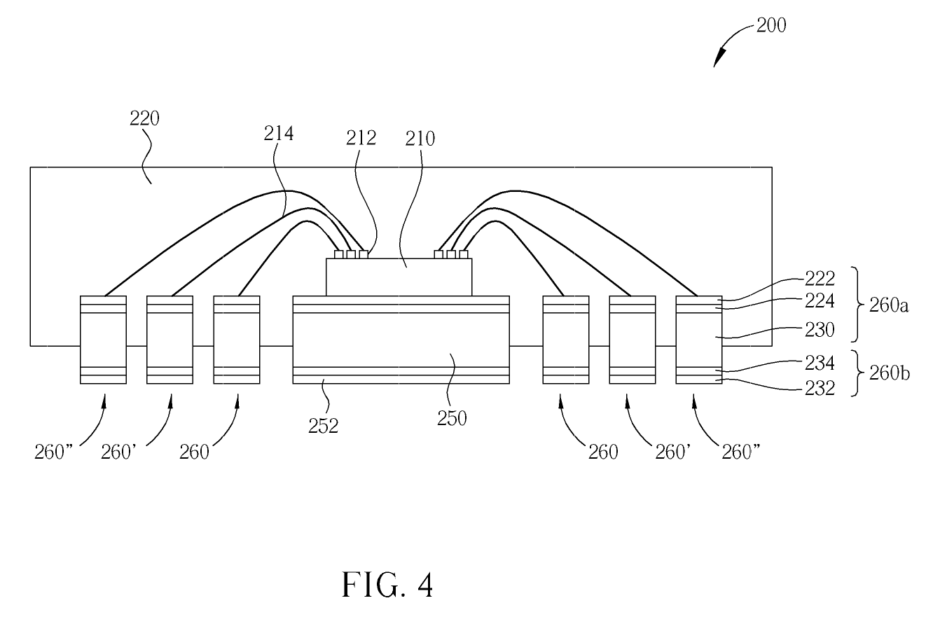

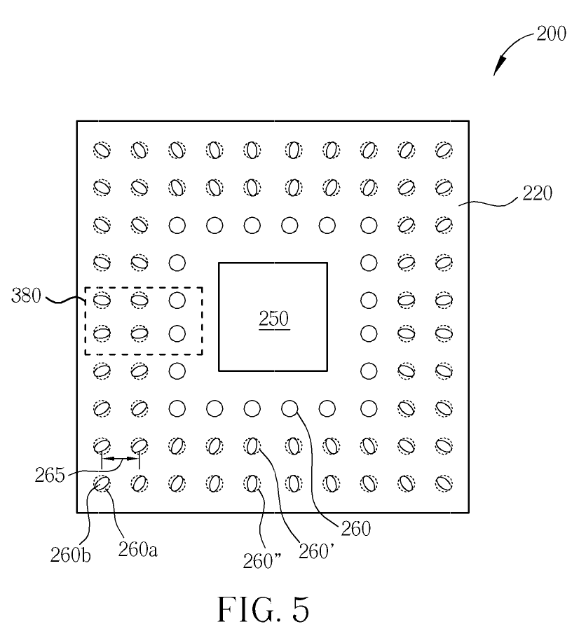

FIG. 4 is a schematic, cross-sectional view of a QFN package 200 according to one embodiment of this invention. FIG. 5 is a bottom view of the QFN package 200 of FIG. 4. As shown in FIG. 4 and FIG. 5, a QFN package 200 comprises a chip 210 attached to a die pad 250, a plurality of inner connection pads 260 disposed about a periphery of the die pad 250, a plurality of middle connection pads 260′ disposed about the inner connection pads 260 and a plurality of outer connection pads 260″ disposed about the middle connection pads 260′. The chip 210 may be attached to the die pad 250 by either a conductive adhesive layer or a nonconductive adhesive layer such as epoxy.

It is understood that in some cases the die pad 250 may be omitted such that only the bottom surface of the chip 210 is exposed from the bottom of the QFN package 200. It is also to be understood that the arrangement of the inner connection pads 260 that encompass the die pad 250 is exemplary. In some cases, some of the inner connection pads 260 may be omitted.

As best seen in FIG. 5, the plurality of inner connection pads 260 are disposed around the die pad 250. The plurality of outer connection pads 260″ are disposed along the four peripheral sides (i.e., the periphery) of the QFN package 200. The middle connection pads 260′ are disposed between the plurality of inner connection pads 260 and the plurality of outer connection pads 260″.

In this embodiment, the die pad 250 and the inner, middle and outer connection pads 260, 260′ and 260″ are provided with a first metal coating which allows a bond to be formed with the bonding wires 214. For example, the first metal coating may comprise a layer of nickel 224 covering the upper surfaces of the die pad 250 and the inner, middle and outer connection pads 260, 260′ and 260″, and a layer of gold or palladium 222 covering the nickel layer 224. The lower surfaces of the die pad 250 and the inner, middle and outer connection pads 260, 260′ and 260″ are covered with a second metal coating. The second metal coating may comprise a layer of nickel 234 covering the lower surfaces of the die pad 250 and the inner, middle and outer connection pads 260, 260′ and 260″, and a layer of gold or palladium 232 covering the nickel layer 234. The second metal coating prevents the lower surfaces of the die pad 250 and the inner, middle and outer connection pads 260, 260′ and 260″ from corrosion or contamination thereby assuring the solder-joint reliability.

A plurality of bonding pads 212 are provided on an active surface of the chip 210 and are electrically connected with the corresponding inner, middle and outer connection pads 260, 260′ and 260″ through, for example, gold wires 214. A package body 220 encapsulates the chip 210, the gold wires 214, an upper portion of the die pad 250 and an upper portion 260a of each of the inner, middle and outer connection pads 260, 260′ and 260″ such that a lower portion 260b of each of the inner, middle and outer connection pads 260, 260′ and 260″ extends outward from the bottom of the package body 220. The package body 220 may be formed by conventional plastic molding methods such as transfer molding, or by other available molding methods.

The QFN package 200 can be mounted onto a substrate, such as a printed circuit board or mother board, like other leadless devices. For example, a solder paste pattern corresponding to the pattern of the inner, middle and outer connection pads 260, 260′ and 260″ exposed from the bottom surface of the package 200 is screen printed onto a printed circuit board. The QFN package 200 is then positioned on the printed circuit board and the solder is reflowed by using the conventional surface mount technology.

As seen in FIG. 5, each of the middle and outer connection pads 260′ and 260″ has an oval shape when viewed from the bottom of the QFN package 200, while each of the inner connection pads 260 has a circular shape when viewed from the bottom of the QFN package 200. In another embodiment, all of the inner, middle and outer connection pads 260, 260′ and 260″ may have an oval shape when viewed from the bottom of the QFN package 200. It should be understood in the context of this invention that the term “oval” as used throughout herein, is meant to encompass shapes that are both truly oval, i.e., having an outline with straight, parallel (or slightly diverging) sides, capped at both ends by a semi-circle (or a segment thereof), as well as those that are elliptical, or egg-shaped, in appearance. According to one embodiment of this invention, merely the lower portion 260b of each of the middle and outer connection pads 260′ and 260″, which extends outward from the bottom of the package body 220, has an oval shape when viewed from the bottom of the QFN package 200. The upper portion 260a of each of the middle and outer connection pads 260′ and 260″ has a circular shape when viewed from the bottom of the QFN package 200. In this manner, a section of the upper circuit portion 260a of each of the middle and outer connection pads 260′ and 260″ is exposed from the bottom of the QFN package 200. However, in another embodiment, both of the upper portion 260a and the lower portion 260b of each of the middle and outer connection pads 260′ and 260″ may have the same oval shape when viewed from the bottom of the QFN package 200.

As shown in FIG. 5, each oval lower portion 260b of the middle and outer connection pads 260′ and 260″ has a major axis and a minor axis when viewed from the bottom of the QFN package 200. The middle and outer connection pads 260′ and 260″ are arranged along the outside edge of the chip 210 such that the major axis of each oval lower portion 260b of the middle and outer connection pads 260′ and 260″ is substantially directed in a radial direction relative to the center of the chip 210. However, it is understood that in some cases the major axis of each oval lower portion 260b of the middle and outer connection pads 260′ and 260″ may be substantially perpendicular to an outside edge of the chip 210. According to this embodiment, the inner, middle and outer connection pads 260, 260′ and 260″ are arranged in a matrix that has one single pitch 265.

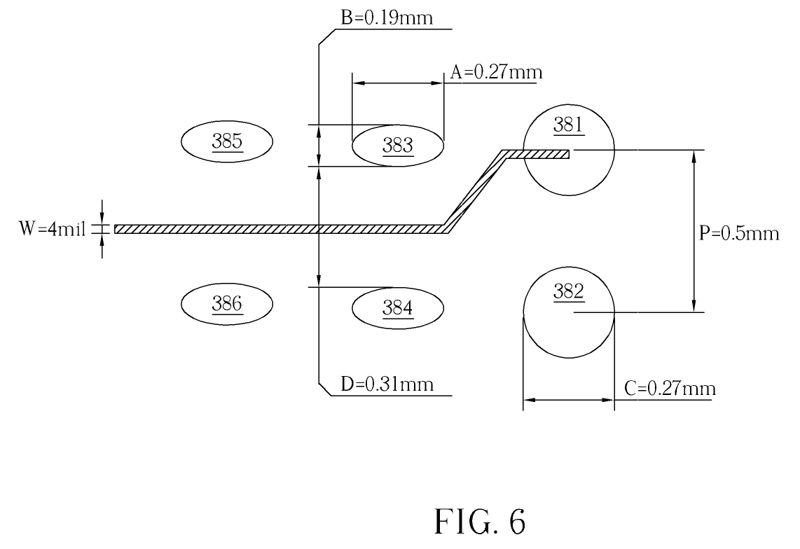

It is one advantage to use the embodiment because the cost of PCB can be significantly reduced. FIG. 6 demonstrates a partial trace layout of a PCB particularly for the QFN package of FIG. 4. For the sake of simplicity, only six solder ball lands 381-386 that correspond to two of the outer connection pads 260″, two of the middle connection pads 260′ and two of the inner connection pads 260 of FIG. 5 as specifically indicated by dashed line region 380 are illustrated.

As shown in FIG. 6, since the inner, middle and outer connection pads 260, 260′ and 260″ are arranged in a matrix that has one single pitch, the solder ball lands 318-386 on the PCB also have one single pitch (P). For example, the distance between the center of the solder ball land 381 and the center of the solder ball land 382 is equal to the distance between the center of the solder ball land 383 and the center of the solder ball land 384. The solder ball lands 383-386 have an oval shape configuration corresponding to the shape of the middle and outer connection pads 260′ and 260″ within the dashed line region 380. Each of the solder ball lands 383-386 has a major axis (A) and a minor axis (B).

According to this embodiment, when a design rule including a pitch (P) of 0.5 mm, a circle land diameter (C) of 0.27 mm, a major axis (A) of about 0.27 mm and a minor axis (B) of 0.19 is employed, a trace width (W) of 4 mil is allowable (in such case, the distance D between the solder ball lands 383 and 384, for example, is approximately 0.31 mm). In another embodiment, it is also possible to route two 3-mil trace lines between the two adjacent solder ball lands 383 and 384 because the space, i.e., the distance D, between the two adjacent solder ball lands 383 and 384 is increased when compared with the prior art. It is also one germane feature of this embodiment that the inner, middle and outer connection pads 260, 260′ and 260″ are arranged in a matrix that has one single pitch, while the space of the middle and outer connection pads 260′ and 260″ is larger than that of the inner connection pads 260.

It is noted that, in one example the major axis (A) of each of the solder ball lands 383-386 on the PCB could be slightly greater than the circle land diameter (C) of each of the solder ball lands 381 and 382 such that the surface area of each of the solder ball lands 383-386 is substantially equal to that of each of the solder ball lands 381 and 382. By doing this, the contact surface area for each of the solder balls may be substantially the same. The joint strength between the ball and ball land is determined by the contact surface area. The undesired solder overflow on the PCB can be avoided by providing substantially the same contact surface area for the ball with equal size. However, the above-described approach should not used to limit the scope of the invention. In other cases, the bottom surface area of each of one of the outer connection pads could be smaller than or equal to that of each of one of the inner connection pads.

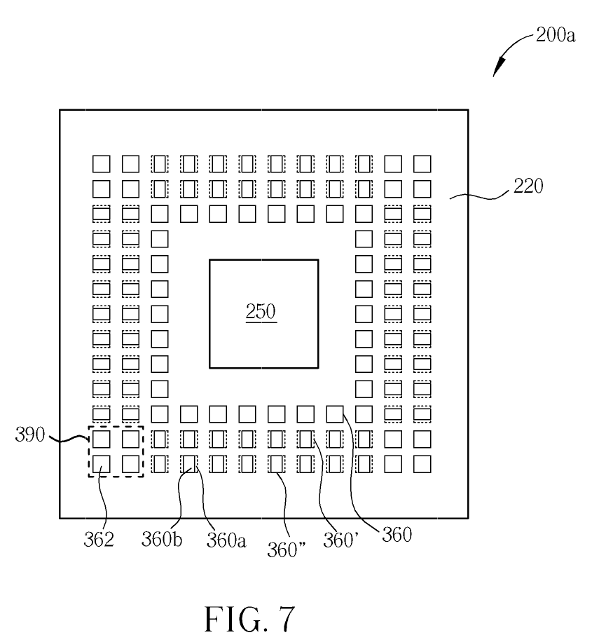

FIG. 7 is a schematic bottom view of a QFN package 200a in accordance with another embodiment of this invention, wherein like numeral numbers designate like layers, regions or elements. As shown in FIG. 7, a QFN package 200a comprises die pad 250 for receiving a chip (not shown in FIG. 7), a plurality of inner connection pads 360 disposed about a periphery of the die pad 250, a plurality of middle connection pads 360′ disposed about the inner connection pads 360 and a plurality of outer connection pads 360″ disposed about the middle connection pads 360′.

A package body 220 encapsulates the upper portion of the die pad 250 and an upper portion 360a of each of the inner, middle and outer connection pads 360, 360′ and 360″ such that a lower portion 360b of each of the inner, middle and outer connection pads 360, 360′ and 360″ extends outward from the bottom of the package body 220. Each lower portion 360b of the middle and outer connection pads 360′ and 360″ has a rectangular shape that has a long side and a short side when viewed from the bottom of the QFN package 200a, while each of the inner connection pads 360 has a square shape when viewed from the bottom of the QFN package 200a. In this embodiment, at the four corners 390 of the bottom of the QFN package 200a, the shape of each of the connection pads 362 (indicated by dashed line region) keeps the same as that of each of the inner connection pads 360. In one example, the dimension of each of the connection pads 362 at the four corners 390 of the bottom of the QFN package 200a is not adjusted and is substantially the same as that of each of the inner connection pads 360.

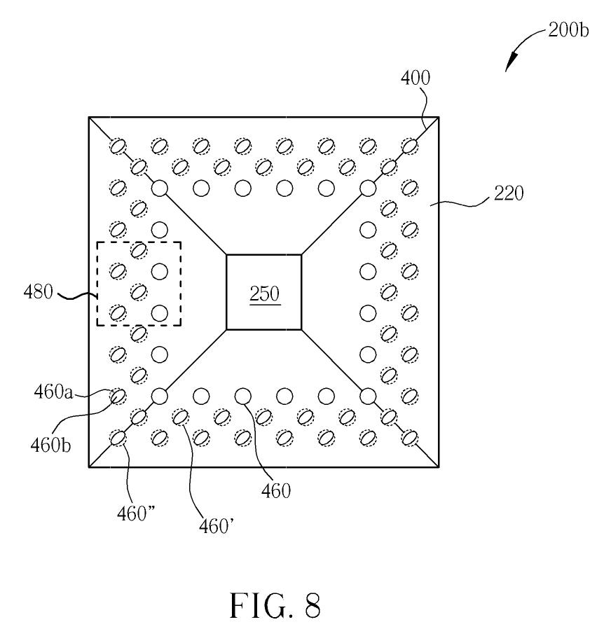

FIG. 8 is a schematic bottom view of a QFN package 200b in accordance with yet another embodiment of this invention, wherein like numeral numbers designate like layers, regions or elements. As shown in FIG. 8, likewise, a QFN package 200b comprises die pad 250 for receiving a chip (not shown in FIG. 8), a plurality of inner connection pads 460 disposed about a periphery of the die pad 250, a plurality of middle connection pads 460′ disposed about the inner connection pads 460 and a plurality of outer connection pads 460″ disposed about the middle connection pads 460′. The inner, middle and outer connection pads 460, 460′ and 460″ are arranged in a staggered configuration.

A package body 220 encapsulates the upper portion of the die pad 250 and an upper portion 460a of each of the inner, middle and outer connection pads 460, 460′ and 460″ such that a lower portion 460b of each of the inner, middle and outer connection pads 460, 460′ and 460″ extends outward from the bottom of the package body 220. Each lower portion 460b of the middle and outer connection pads 460′ and 460″ has an oval shape when viewed from the bottom of the QFN package 200b, while each of the inner connection pads 460 has a circular shape when viewed from the bottom of the QFN package 200b.

The QFN package 200b has a diagonal line 400 and the major axis of each of the oval lower portion 460b of the middle and outer connection pads 460′ and 460″ is directed in parallel with the diagonal line 400. According to this embodiment, the inner, middle and outer connection pads 460, 460′ and 460″ are arranged in a matrix that has one single pitch.

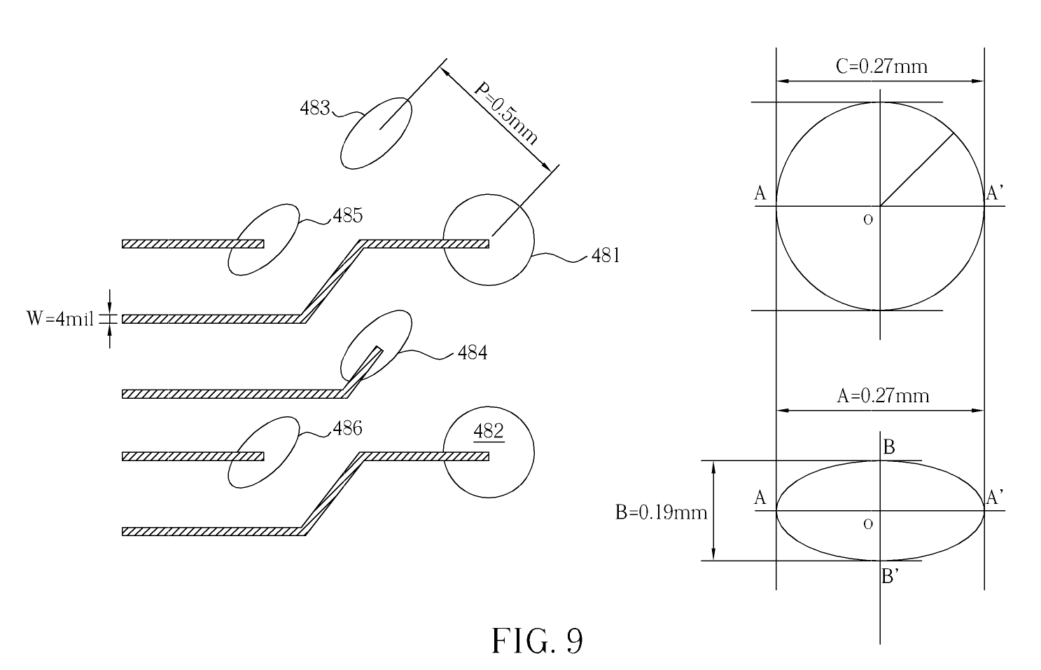

FIG. 9 demonstrates a partial trace layout of a PCB particularly for the QFN package 200b of FIG. 8. For the sake of simplicity, only six solder ball lands 481-486 that correspond to two of the outer connection pads 460″, two of the middle connection pads 460′ and two of the inner connection pads 460 of FIG. 8 as specifically indicated by dashed line region 480 are illustrated. As shown in FIG. 9, the solder ball lands 418-486 on the PCB also have one single pitch (P). For example, the distance between the center of the solder ball land 481 and the center of the adjacent solder ball land 483 is equal to the distance between the center of the solder ball land 484 and the center of the adjacent solder ball land 485.

The solder ball lands 483-486 have an oval shape configuration corresponding to the shape of the middle and outer connection pads 460′ and 460″ within the dashed line region 480. Each of the solder ball lands 483-486 has a major axis (A) and a minor axis (B). According to this embodiment, when a design rule including a pitch (P) of 0.5 mm, a circle land diameter (C) of 0.27 mm, a major axis (A) of about 0.27 mm and a minor axis (B) of 0.19 is employed, and since the major axes of the oval solder ball lands 483-486 are also aligned with the diagonal line 400, a trace width (W) of 4 mil is allowable.

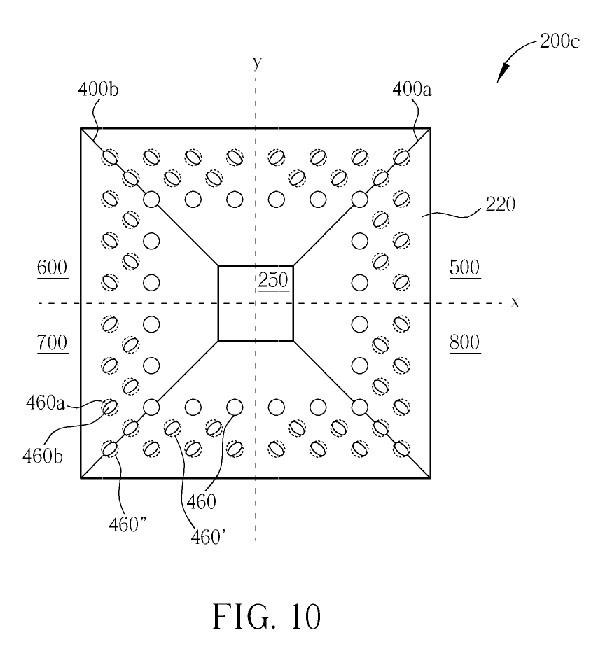

FIG. 10 is a schematic bottom view of a QFN package 200c in accordance with yet another embodiment of this invention, wherein like numeral numbers designate like layers, regions or elements. As shown in FIG. 10, a QFN package 200c comprises die pad 250 for receiving a chip (not shown in FIG. 10), a plurality of inner connection pads 460 disposed about a periphery of the die pad 250, a plurality of middle connection pads 460′ disposed about the inner connection pads 460 and a plurality of outer connection pads 460″ disposed about the middle connection pads 460′. The inner, middle and outer connection pads 460, 460′ and 460″ are arranged in a staggered configuration.

A package body 220 encapsulates the upper portion of the die pad 250 and an upper portion 460a of each of the inner, middle and outer connection pads 460, 460′ and 460″ such that a lower portion 460b of each of the inner, middle and outer connection pads 460, 460′ and 460″ extends outward from the bottom of the package body 220. Each lower portion 460b of the middle and outer connection pads 460′ and 460″ has an oval shape when viewed from the bottom of the QFN package 200b, while each of the inner connection pads 460 has a circular shape when viewed from the bottom of the QFN package 200b.

The QFN package 200b has a diagonal line 400a and a diagonal line 400b. The inner, middle and outer connection pads 460, 460′ and 460″ can be grouped into four sets that are disposed in four quadrant regions 500, 600, 700 and 800, which are defined by the schematic dashed coordinate x- and y-axes. In this embodiment, the major axis of each of the oval lower portion 460b of the middle and outer connection pads 460′ and 460″ within the quadrant regions 500 and 700 is directed in parallel with the diagonal line 400a, while the major axis of each of the oval lower portion 460b of the middle and outer connection pads 460′ and 460″ within the quadrant regions 600 and 800 is directed in parallel with the diagonal line 400b.

Those skilled in the art will readily observe that numerous modifications and alterations of the device and method may be made while retaining the teachings of the invention.

What is claimed is:

1. A semiconductor chip package, comprising:
a chip;
a plurality of inner connection pads disposed about a periphery of the chip;
a plurality of outer connection pads disposed between the plurality of inner connection pads and a periphery of the semiconductor chip package, wherein one of the outer connection pads has an oval shape when viewed from a bottom of the semiconductor chip package;
a plurality of bonding pads provided on an active surface of the chip and being electrically connected with corresponding said inner and outer connection pads through bonding wires; and
a package body encapsulating the chip, the bonding wires and an upper portion of each of the inner and outer connection pads such that a lower portion of each of the inner and outer connection pads extends outward from a bottom of the package body.

2. The semiconductor chip package according to claim 1 wherein one of the inner connection pads has a circular shape when viewed from the bottom of the semiconductor chip package.

3. The semiconductor chip package according to claim 1 wherein one of the inner connection pads has a square shape when viewed from the bottom of the semiconductor chip package.

4. The semiconductor chip package according to claim 1 wherein the semiconductor chip package is a quad flat non-lead (QFN) package.

5. The semiconductor chip package according to claim 1 further comprising a die pad, and wherein the chip is attached to the die pad.

6. The semiconductor chip package according to claim 1 wherein the inner and outer connection pads are arranged in a matrix that has one single pitch.

7. The semiconductor chip package according to claim 1 wherein the plurality of inner connection pads has a first space between two of the inner connection pads, and the plurality of outer connection pads has a second space between two of the outer connection pads, and wherein the second space is larger than the first space.

8. The semiconductor chip package according to claim 1 wherein each said lower portion of the outer connection pads has a major axis and a minor axis, and the major axis is substantially directed in a radial direction relative to a center of the chip.

9. The semiconductor chip package according to claim 1 wherein each said lower portion of the outer connection pads has a major axis and a minor axis, and the major axis is substantially perpendicular to an outside edge of the chip.

10. The semiconductor chip package according to claim 1 wherein each said lower portion of the outer connection pads has a major axis and a minor axis, and the major axis is directed in a diagonal direction that is in parallel with a diagonal line of the semiconductor chip package.

11. A quad flat non-lead (QFN) package, comprising:
a chip;
a plurality of first and second connection pads arranged in a matrix and disposed about the chip, wherein the first and second connection pads have different bottom surface shapes when viewed from a bottom of the QFN package;
a plurality of bonding pads provided on an active surface of the chip and being electrically connected with corresponding said connection pads through bonding wires; and
a package body encapsulating the chip, the bonding wires and an upper portion of each of the connection pads such that a lower portion of each of the connection pads extends outward from a bottom of the package body.

12. The QFN package according to claim 11 wherein the matrix of the first and second connection pads is radially symmetrical about a center of the chip.

13. The QFN package according to claim 11 wherein the matrix of the first and second connection pads has one single pitch.

14. The QFN package according to claim 11 further comprising a die pad, and wherein the chip is attached to the die pad.

15. The QFN package according to claim 11 wherein the first connection pads are inner connection pads and the second connection pads are outer connection pads, and wherein the bottom surface area of one of the outer connection pads is smaller than or equal to that of one of the inner connection pads.

16. The QFN package according to claim 15 wherein one of the bottom surface area of the outer connection pads is oval shaped and has a major axis and a minor axis, and wherein the major axis is substantially directed in a radial direction relative to a center of the chip.

17. The QFN package according to claim 15 wherein one of the bottom surface area of the outer connection pads is oval shaped and has a major axis and a minor axis, and wherein the major axis is substantially perpendicular to an outside edge of the chip.

18. The QFN package according to claim 15 wherein one of the bottom surface area of the outer connection pads is oval shaped and has a major axis and a minor axis, and wherein the major axis is substantially directed in a diagonal direction that is in parallel with a diagonal line of the QFN package.

19. The QFN package according to claim 11 wherein one of the bottom surface area of the outer connection pads is rectangular shaped and has a long side and a short side.

20. A semiconductor chip package, comprising:
a chip;
a plurality of inner connection pads disposed about a periphery of the chip;
a plurality of outer connection pads disposed between the plurality of inner connection pads and the periphery of the chip, wherein one of the outer connection pads has a rectangular shape with a long side and a short side when viewed from a bottom of the semiconductor chip package;
a plurality of bonding pads provided on an active surface of the chip and being electrically connected with corresponding said inner and outer connection pads through bonding wires; and
a package body encapsulating the chip, the bonding wires and an upper portion of each of the inner and outer connection pads such that a lower portion of each of the inner and outer connection pads extends outward from a bottom of the package body.
